(19) United States
(12) Patent Application Publication
(10) Pub. No.: US 2021/0313004 A1
(43) Pub. Date: Oct. 7, 2021

(54) MEMORY

(71) Applicant: FUJITSU LIMITED, Kawasaki-shi (JP)

(72) Inventor: Yoshitsugu Goto, Kawasaki (JP)

(73) Assignee: FUJITSU LIMITED, Kawasaki-shi (JP)

(21) Appl. No.: 17/164,946

(22) Filed: Feb. 2, 2021

(30) Foreign Application Priority Data
Apr. 2, 2020 (JP) 2020-066875

(51) Int. Cl. G11C 29/44; G11C 29/24; G11C 29/00; G11C 29/10; G11C 7/10

(52) U.S. Cl. CPC G11C 29/44; G11C 29/24; G11C 7/1012; G11C 29/10; G11C 29/76

(57) ABSTRACT

A memory includes a plurality of memory dies that includes a plurality of memory regions stacked on each other, the plurality of memory regions including a memory cell region that stores data and a redundant cell region that stores data as an alternative when a part of the memory cell region fails; a multiplexer that outputs data supplied to a local memory region or data supplied to another memory region to the redundant cell region of the local memory region on a basis of an input selection signal from outside; and a selector that outputs data output from the redundant cell region of the local memory region or data output from the redundant cell region of the other memory region to a data terminal of the local memory region on a basis of an output selection signal from outside.

### CROSS-REFERENCE TO RELATED APPLICATION

This application is based upon and claims the benefit of priority of the prior Japanese Patent Application No. 2020-66875, filed on Apr. 2, 2020, the entire contents of which are incorporated herein by reference.

### FIELD

The embodiments discussed herein are related to a memory.

### BACKGROUND

Recently, a data amount used by a processor such as a central processing unit (CPU) has tended to increase, and a storage capacity of a memory accessed by the processor has also tended to increase. In order to suppress an increase in an access latency due to the increase in the storage capacity, a stacked memory that reduces a load capacity of wiring by stacking a plurality of memory dies has been used.

This type of stacked memory includes, for example, a plurality of memory chips including a memory block portion and a redundant block portion, and a redundant memory chip including only a redundant block portion. Then, by using any one of a local memory chip, another memory chip, or a redundant block portion of a redundant memory chip instead of a memory block portion in which a failure is detected, the failed memory block portion is relieved.

Furthermore, in this type of stacked memory, each memory chip includes a redundant row memory cell and a redundant column memory cell, a storage circuit that stores a failure address of the local memory chip or the other memory chip, and a matching determination unit that determines whether or not the failure address matches with an address from outside. Then, each memory chip determines whether or not to access the redundant row memory cell or the redundant column memory cell on the basis of the matching determination made by the matching determination unit regarding whether or not the failure address stored in the storage circuit matches with the address from outside. Japanese Laid-open Patent Publication No, 2015-135577, Japanese Laid-open Patent Publication No. 2005-100517, and the like are disclosed as related art.

### SUMMARY

According to an aspect of the embodiments, a memory includes a plurality of memory dies that includes a plurality of memory regions stacked on each other, the plurality of memory regions including a memory cell region that stores data and a redundant cell region that stores data as an alternative when a part of the memory cell region fails; a multiplexer that outputs data supplied to a local memory region or data supplied to another memory region to the redundant cell region of the local memory region on a basis of an input selection signal from outside; and a selector that outputs data output from the redundant cell region of the local memory region or data output from the redundant cell region of the other memory region to a data terminal of the local memory region on a basis of an output selection signal from outside.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a block diagram illustrating an example of a memory according to one embodiment;

FIG. 2 is a block diagram illustrating an example of a memory according to another embodiment;

FIG. 3 is a side view illustrating an example of a stacked structure of the memory in FIG. 2;

FIG. 4 is a block diagram illustrating an example of a memory die in FIG. 2;

FIG. 5 is an explanatory diagram illustrating an example in which a failure occurs in each channel in FIG. 4 is relieved by a redundant cell region;

FIG. 6 is an explanatory diagram illustrating an example of a repair share register in FIG. 4;

FIG. 7 is a block diagram illustrating an example of a normal operation that does not use the redundant cell region in the memory in FIG. 2;

FIG. 8 is a block diagram illustrating an example of an alternative operation using the redundant cell region in the memory in FIG. 2;

FIG. 9 is a block diagram illustrating another example of the alternative operation using the redundant cell region in the memory in FIG. 2;

FIG. 10 is a block diagram illustrating still another example of the alternative operation using the redundant cell region in the memory in FIG. 2;

FIG. 11 is a flow diagram illustrating an example of an operation of a test circuit in FIG. 2;

FIG. 12 is a flow diagram illustrating an example of an operation in step S16 in FIG. 11;

FIG. 13 is a flow diagram illustrating an example of an operation in step S20 in FIG. 11;

FIG. 14 is a flow diagram illustrating an example of an operation of a memory controller that controls a writing operation of the memory in FIG. 2;

FIG. 15 is a flow diagram illustrating an example of an operation of the memory controller that controls a reading operation of the memory in FIG. 2; and

FIG. 16 is an explanatory diagram illustrating an example of a bank configuration of the memory in FIG. 2.

### DESCRIPTION OF EMBODIMENTS

However, in a case where a failure address stored in a storage unit is compared with an address from outside by a matching determination unit, after an access request is supplied to a stacked memory, it is determined whether or not to access a redundant row memory cell or a redundant column memory cell in each memory chip. Therefore, an access latency for determination time occurs and also, a circuit size of the memory chip increases.

In view of the above, it is desirable to suppress an increase in an access latency in a case where a failure in a part of a memory cell region is replaced with a redundant cell region of a local memory region or another memory region.

Hereinafter, embodiments will be described with reference to the drawings. In the following, a reference same as a signal name is used for a signal line and a terminal to which signals are transmitted. Furthermore, a single signal line in the drawings may include a plurality of signal lines.

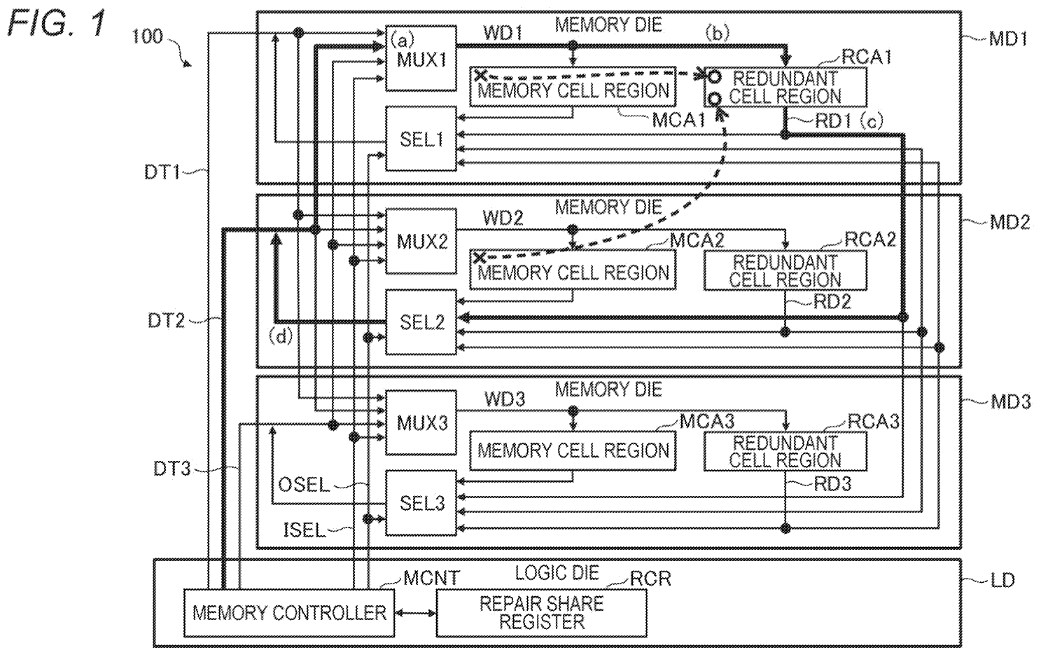

FIG. 1 illustrates an example of a memory according to an embodiment. A memory 100 illustrated in FIG. 1 is a stacked memory and includes a plurality of memory dies MD (MD1, MD2, and MD3) and a logic die LD stacked on each other. The number of stacked memory dies MD is not limited to that in FIG. 1 as long as the number is equal to or more than two. The logic die LD includes a memory controller MCNT and a repair share register RCR. The memory die MD is an example of a memory region. The memory controller MCNT is an example of an access control unit. The repair share register RCR is an example of an alternative information holding unit.

The memory controller MCNT and each memory die MD are mutually connected by a dedicated data line DT (DT1, DT2, and DT3) for each memory die MD. The data line DT is connected to a data terminal (not illustrated) of each memory die MD. For example, although each data line DT is a bidirectional data bus, each data line DT may include a writing data bus and a reading data bus. Note that the data line DT2 or the like that is thicker than other signal lines is used for explanation of an operation of the memory 100 described later and does not indicate a difference in specifications such as a bit number.

For example, each memory die MD and the logic die ID are provided with a through silicon via (TSV), and connection between the memory dies MD facing each other and connection between the memory die MD and the logic die LD are made by connecting the TSVs via bumps. The TSV is an example of a through electrode. In an intersection between an outer peripheral line of each of the memory dies MD and logic die LD and a signal line illustrated in FIG. 1, an external terminal (input terminal or output terminal) (not illustrated) is provided.

Because each of the memory dies MD1, MD2, and MD3 have the similar configuration, the memory die MD1 will be mainly described below. By replacing “1” at the end of the reference in the following description regarding the memory die MD1 with “2” or “3” and replacing each of “2” or “3” at the end of the reference with a number other than “2” and “3”, it becomes the description of the memory die MD2 or the memory die MD3.

The memory die MD1 includes a memory cell region MCA1, a redundant cell region RCA1, a multiplexer MUX1, a selector SEL1, and a plurality of signal lines connected to these elements. The signal line illustrated in FIG. 1 indicates a data line, and an address line and a control signal line are not illustrated. Each multiplexer MUX (MUX1 to MUX3) is an example of an input selection unit. Each selector SEL (SEL1 to SEL3) is an example of an output selection unit. Note that a plurality of memory regions each including the memory cell region MCA, the redundant cell region RCA, the multiplexer MUX, and the selector SEL may be stacked in the single memory die MD.

The memory cell region MCA1 includes a plurality of memory cells that stores data. For example, memory cells in the memory cell region MCA1 are arranged in a matrix, memory cells arranged in a row direction are connected to a common word line, and memory cells arranged in a column direction orthogonal to the row direction are connected to a common data line (bit line).

The redundant cell region RCA1 includes a redundant memory cell that stores data instead of an inaccessible memory cell in a case where it is not possible to access some memory cells in the memory cell region MCA1 due to a failure. In the following, an alternative of the memory cell is referred to as relief of the memory cell.

For example, the redundant cell region RCA1 relieves memory cells in word line units in the memory cell region MCA1. In this case, the redundant cell region RCA1 includes at least one redundant word line and a plurality of redundant memory cells connected to the redundant word line. Alternatively, the redundant cell region RCA1 relieves memory cells in data line units in the memory cell region MCA1. In this case, the redundant cell region RCA1 includes at least one redundant data line and a plurality of redundant memory cells connected to the redundant data line. In the following, description will be made as assuming that each of the redundant cell regions RCA1, RCA2, and RCA3 includes two redundant word lines.

One of inputs of the multiplexer MUX1 is connected to an output of the memory controller MCNT via the data line DT1 for the memory die MD1. Other inputs of the multiplexer MUX1 are connected to the data line DT2 for the memory die MD2 and the data line DT3 for the memory die MD3. The data lines DT2 and DT3 are each connected to outputs of the memory controller MCNT.

The multiplexer MUX1 operates at the time of a writing operation, and connects the data line DT1 to a writing data line WD1 on the basis of an input selection signal ISEL from the memory controller MCNT in a case where data is written to the memory cell region MCA1 or the redundant cell region RCA1. In a case where data is written to the redundant cell region RCA1 instead of the memory cell regions MCA2 and MCAS as an alternative of some failures, the multiplexer MUX1 connects one of the data lines DT2 or DT3 to the writing data line WD1 on the basis of the input selection signal ISEL.

One of inputs of the selector SEL1 is connected to an output of the memory cell region MCA1. Another input of the selector SEL1 is connected to an output of the redundant cell region RCA1 via a reading data line RD1. Still another input of the selector SEL1 is connected to an output of the redundant cell region RCA2 of the memory die MD2 via a reading data line RD2. Yet another input of the selector SEL1 is connected to an output of the redundant cell region RCA3 of the memory die MD3 via a reading data line RD3.

The selector SEL1 operates at the time of a reading operation, and connects the output of the memory cell region MCA1 to the data line DT1 in a case where data is read from the memory cell region MCA1 of the local memory die MD1. The selector SEL1 connects the reading data line RD1 to the data line DT1 in a case where data for the local memory die MD1 held in the redundant cell region RCA1 of the local memory die MD1 is read. The selector SEL1 connects the reading data line RD2 (or RD3) to the data line DT1 in a case where data for the local memory die MD1 held in the redundant cell region RCA2 (or RCA3) of the other memory die MD2 (or MD3) is read.

In this embodiment, write data is transferred via a common transfer path in a case where the data is written to either one of the memory cell region MCA1 or the redundant cell region RCA1. Furthermore, read data is transferred via a common path in the memory die MD1 in a case where the data is read from either one of the memory cell region MCA1 or the redundant cell region RCA1. Furthermore, a thickness of the memory die MD is, for example, a several tens microns. Because the memory dies MD are connected via the TSV, a signal transfer delay between the memory dies MD can be equivalent to a signal transfer delay in the memory die MD. Therefore, even in a case where a failure of the memory die MD1 is relieved by the redundant cell region RCA2 of the memory die MD2, an access latency of reading and writing data can be equivalent to an access latency of reading and writing data from and to the memory cell region MCA1.

The memory controller MCNT generates various control signals on the basis of an access request (writing request or reading request) from a processor (not illustrated) and controls an access operation (writing operation and reading operation) of each memory die MD, The memory controller MCNT performs redundant determination for determining whether or not the redundant cell region RCA is accessed and determining a redundant cell region RCA to be accessed by referring to the repair share register RCR in response to the access request.

The repair share register RCR holds a usage status of the redundant cell region RCA, an address (failure address) indicating a part of a failed memory cell region MCA, and alternative information indicating that the failure of the local memory die is replaced with a redundant cell region RCA of another memory die. The memory controller MCNT determines whether or not a part of an address (for example, lower address except for memory die MD selection address) included in the access request is held in the repair share register RCR as a failure address.

In a case where a part of the address included in the access request is not the failure address, the memory controller MCNT generates an access control signal that causes an access to the memory cell region MCA of the memory die MD indicated by the address included in the access request. Then, the memory controller MCNT outputs the generated access control signal to the memory die MD to be accessed indicated by the access request.

In a case where the address included in the access request is the failure address, the memory controller MCNT confirms which redundant cell region RCA is an alternative on the basis of the usage status of the redundant cell region RCA held in the repair share register RCR. Moreover, the memory controller MCNT confirms which one of the memory die MD to be accessed (local memory die) and a memory die MD not to be accessed (other memory die) includes the alternative redundant cell region RCA on the basis of the alternative information.

Then, the memory controller MCNT generates an access control signal corresponding to the access request on the basis of various information held in the repair share register RCR. The memory controller MCNT outputs the generated access control signal to a data writing target memory die MD or a data reading target memory die MD. The access control signal includes an access command to be output to the memory cell region MCA or the redundant cell region RCA, the input selection signal ISEL to be output to the multiplexer MUX, and an output selection signal OSEL to be output to the selector SEL.

Note that the memory controller MCNT includes a request buffer (not illustrated) that holds the access request from the processor. The memory controller MCNT refers to the repair share register RCR using the information held in the request buffer and performs the redundant determination for determining whether or not the redundant cell region RCA is accessed and for determining the redundant cell region RCA to be accessed.

Therefore, the memory controller MCNT can perform the access operation in response to the access request and the redundant determination on the access operation to be executed thereafter in parallel, and can make time needed for the redundant determination be invisible. Therefore, the access latency can be shortened in comparison with a case where a redundant determination circuit that executes the redundant determination on the basis of reception of the access command is provided in each memory die MD.

Next, the access operation (writing operation and reading operation) of the memory 100 in FIG. 1 will be described. For example, it is assumed that, due to failures occurred in a part of the memory cell regions MCA1 and MCA2, each of the word lines of the memory cell regions MCA1 and MCA2 be replaced with the two redundant word lines of the redundant cell region RCA1. The X mark in FIG. 1 indicates a failure, and a dashed arrow and a thick circle indicate that the failure is replaced with the redundant cell region RCA1.

It is assumed that an address included in a writing request indicate a defective portion of the memory cell region MCA2. In this case, write data input from the memory controller MCNT to the memory die MD2 via the data line DT2 is input to the multiplexer MUX1 of the memory die MD1 via the memory die MD2 (FIG. 1(a)).

The multiplexer MUX1 outputs write data transferred from the data line DT2 on the basis of the input selection signal ISEL to the redundant cell region RCA1 via the writing data line WD1 (FIG. 1(b)). Then, the write data is stored in the redundant cell region RCA1 on the basis of a write access control signal output from the memory controller MCNT to the memory die MD1. In other words, for example, the write data that is included in the access request for the memory die MD2 and is supplied from the data line DT2 for the memory die MD2 to the memory die MD2 is written to the redundant cell region RCA1 of the memory die MD1.

On the other hand, it is assumed that an address included in a reading request indicate a defective portion of the memory cell region MCA2. In this case, read data is output from the redundant cell region RCA1 to the reading data line RD1 on the basis of a reading access control signal output from the memory controller MCNT to the memory die MD1 (FIG. 1(c)).

The selector SEL2 selects the read data on the reading data line RD1 on the basis of the output selection signal OSEL and outputs the selected read data to the data line DT2 so as to transfer the data to the memory controller MCNT (FIG. 1(d)). In other words, for example, the data to be read in response to the access request for the memory die MD2 is read from the redundant cell region RCA1 of the memory die MD1 and is transferred from the data line DT2 for the memory die MD2 to the memory controller MCNT.

As described above, in the embodiment illustrated in FIG. 1, when the failure is relieved, it is possible to select which one of the redundant cell regions RCA of the local memory die MD and the other memory die MD is used on the basis of the input selection signal ISEL and the output selection signal OSEL from the memory controller MCNT. Each memory die MD can determine whether or not to use the redundant cell region RCA without comparing the access address supplied from the memory controller MCNT with the failure address.

In other words, for example, the failure can be relieved without mounting a storage circuit or a fuse circuit that stores the failure address and a comparison circuit for comparing the access address with the failure address in each memory die MD. In other words, for example, by controlling the operations of the multiplexer MUX and the selector SEL on the basis of an external signal, the redundant cell region RCA that relieves the failure can be selected. As a result, an increase in the access latency can be suppressed as compared with a case where whether or not to replace the failure in a part of the memory cell region MCA with the redundant cell region RCA of the local memory die MD or the other memory die MD is determined in the memory die MD. Furthermore, because the storage circuit or the fuse circuit that stores the failure address and the comparison circuit are not mounted in each memory die MD, an increase in a circuit size of the memory die MD can be suppressed. Moreover, because a program process for programming the failure address in the fuse circuit or the like after the memory dies MD are assembled into a stacked memory is not performed, a yield caused by a defect occurred in the program process is not lowered. Therefore, it is possible to reduce waste such that the stacked memory is discarded due to the defect occurred in the program process, and an increase in manufacturing cost of the stacked memory can be suppressed.

By providing the repair share register RCR that stores information indicating a failure portion of each memory die MD and information indicating a position of the alternative redundant cell region RCA in the logic die ID, the memory controller MCNT can perform the redundant determination for determining whether or not to perform replacement. With this operation, the memory controller MCNT can perform the redundant determination while holding the access request received from outside (before issuing access command to memory die MD), and can make the time needed for the redundant determination be invisible. Therefore, as described above, the increase in the access latency caused by the redundant determination can be suppressed.

In a case where the failure portion of the memory cell region MCA is replaced with the redundant cell region RCA of the other memory die MD, the multiplexer MUX can supply the write data supplied to the memory die MD to be accessed to the redundant cell region RCA of the other memory die MD. Furthermore, in a case where the failure portion of the memory cell region MCA is replaced with the redundant cell region RCA of the other memory die MD, the selector SEL can output the read data read from the redundant cell region RCA of the other memory die MD from the memory die MD to be accessed. As a result, even in a case where the data line DT is independent for each memory die MD, data can be input/output to/from the memory die MD to be accessed regardless of the position of the memory die MD including the redundant cell region RCA to/from which the data is input/output.

The memory controller MCNT and the memory dies MD1 to MD3 are respectively connected by the dedicated data lines DT1 to DT3. Then, the memory controller MCNT outputs the write data to the data line DT corresponding to the memory die MD that is a target of the access request, regardless of the memory die MD in which the redundant cell region. RCA which is replaced with the failure is arranged. Furthermore, the memory controller MCNT receives the read data from the data line DT corresponding to the memory die MD that is the target of the access request. As a result, the memory controller MCNT can control the writing operation and the reading operation of the memory 100 without, for example, switching the path of the data lines, through which data is transferred, in the memory controller MCNT.

The multiplexer MUX of each memory die MD and each of the data lines DT1 to DT3 are connected to each other via the TSVs. Furthermore, the selector SEL of each memory die MD and the redundant cell region RCA of each of the memory dies MD1 to MD3 are connected to each other via the TSVs. Therefore, a signal transfer delay between the memory dies MD can be equivalent to a signal transfer delay in the memory die MD. Therefore, for example, even in a case where a failure of the memory die MD1 is relieved by the redundant cell region RCA2 of the memory die MD2, an access latency of reading and writing data can be equivalent to an access latency of reading and writing data from and to the memory cell region MCA1.

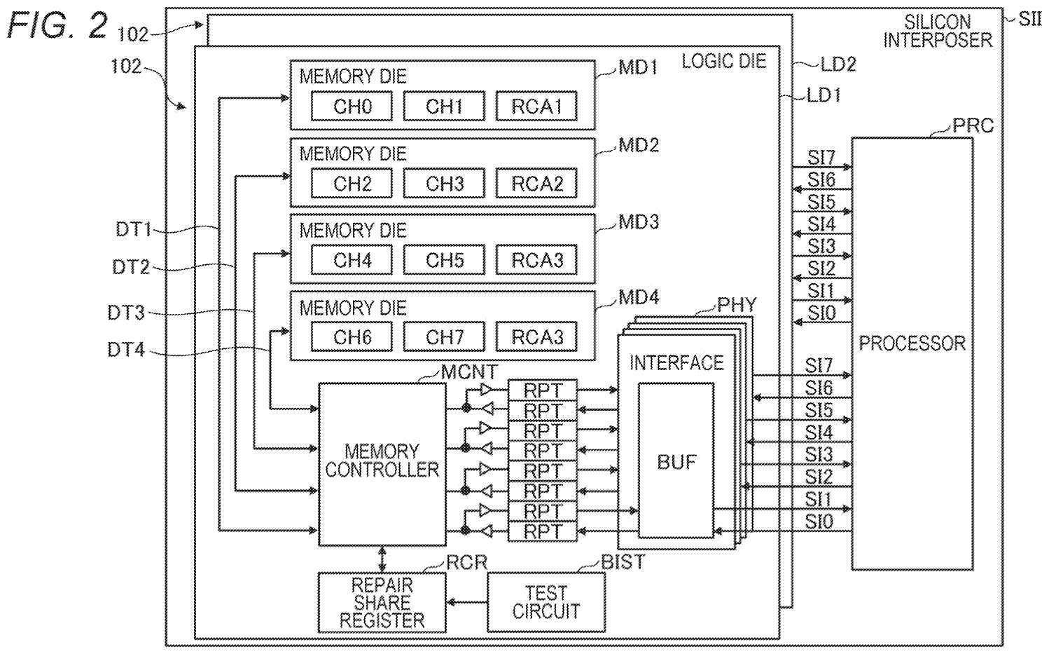

FIG. 2 illustrates an example of a memory according to another embodiment. Detailed description of elements similar to those in FIG. 1 will be omitted. A memory 102 illustrated in FIG. 2 is a stacked memory and includes a logic die LD (LD1 or LD2) and a plurality of memory dies MD (MD1, MD2, MD3, and MD4) stacked on each logic die W. Each memory 102 (logic dies LD1 and LD2) is connected to a processor PRC via a silicon interposer SIT.

Each logic die LD includes a memory controller MCNT, a repair share register RCR, a test circuit BIST, a plurality of repeaters RPT, and a plurality of interfaces PHY. Because the logic dies LD1 and LD2 have the same configuration, the logic die LD1 will be described below.

The number of stacked memory dies MD is not limited to that in FIG. 2 as long as the number is equal to or more than two. For example, as in FIG. 1, connection between each memory die MD and the logic die LD and connection between the memory dies MD are made by connecting the TSVs via bumps.

The memory die MD1 includes memory cell regions CH0 and CH1 and a redundant cell region RCA1. The memory die MD2 includes memory cell regions CH2 and CH3 and a redundant cell region RCA2. The memory die MD3 includes memory cell regions CH4 and CH5 and a redundant cell region RCA3. The memory die MD4 includes memory cell regions CH6 and CH7 and a redundant cell region RCA4.

The memory cell regions CH (CH0 to CH7) have the same configuration and have the same storage capacity with each other. Hereinafter, the memory cell region CH is also referred to as a channel CH. Memory cells in each channel CH are arranged in a matrix, memory cells arranged in a row direction are connected to a common word line, and memory cells arranged in a column direction orthogonal to the row direction are connected to a common data line (bit line).

Each redundant cell region RCA (RCA1, RCA2, RCA3, and RCA4) includes a plurality of redundant memory cells connected to two redundant word lines and relieves a failure that occurs in any one of channels CH in word line units. The word line to be relieved may be not only the channel CH of the local memory die MD but also the channel CH of the other memory die MD.

The memory controller MCNT is connected to a data terminal (not illustrated) of each memory die MD via the data line DT (DT1, DT2, DT3, and DT4). Furthermore, the memory controller MCNT is connected to the repeater RPT via a buffer indicated by a small triangle in FIG. 2, an input data line, and an output data line. Note that the buffer and the repeater RPT are provided for each signal line.

A pair of the input data line and the output data line and a pair of the repeaters RPT corresponding to the pair of the input data line and the output data line each correspond to the data lines DT1 to DT4. The pair of the repeaters RPT is connected to any one of buffer circuits BUF of the plurality of interfaces PHY.

The buffer circuit BUF converts a parallel signal received from the memory controller MCNT into a series signal and outputs the converted series signal to the processor PRC via serial interfaces SI (SI1, SI3, SI5, and SI7). Furthermore, the buffer circuit BUF converts the series signal received from the processor PRC via the serial interfaces SI (SI0, SI2, SI4, and SI6) into the parallel signal and outputs the converted parallel signal to the memory controller MCNT.

The test circuit built-in self test (BIST) operates, for example, when the processor PRC is turned on and performs an operation test of each memory die MD. Then, the test circuit BIST stores, for example, the failure address and information regarding the word line to be replaced to relieve the failure in the repair share register RCR on the basis of the test result.

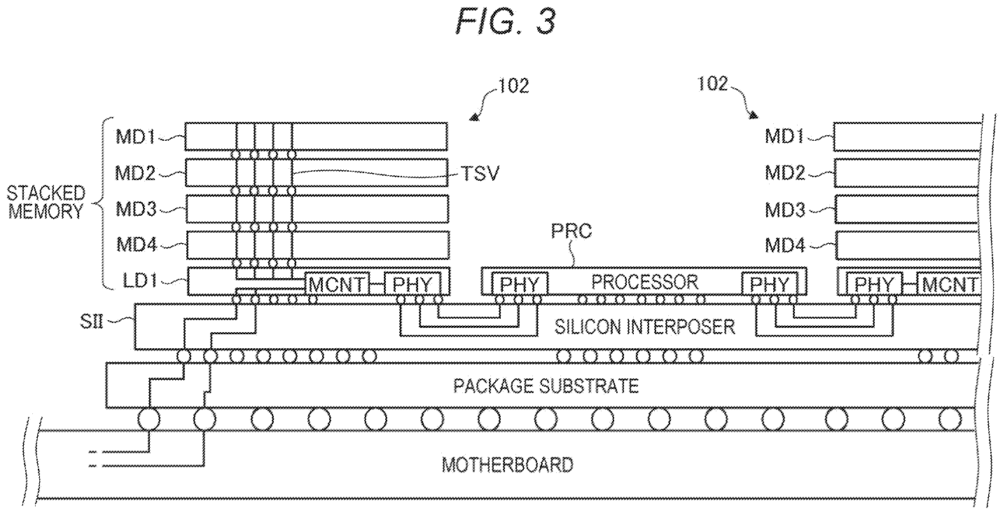

FIG. 3 illustrates an example of a stacked structure of the memory 102 in FIG. 2. FIG. 3 illustrates an example in which the silicon interposer SII in FIG. 2 is mounted on a package substrate and further, the package substrate is connected to a motherboard. The memory die MD and the logic die LD are connected to each other via the bump indicated by a small circle and the TSV.

The processor PRC includes the interface PHY used to communicate with the interface PHY of the logic die LD. The interface PHY of the processor PRC and the interface PHY of the logic die LD are connected to each other via the silicon interposer SII. Furthermore, the logic die LD is connected to the silicon interposer SII via the bump, and the processor PRC is connected to the silicon interposer SII via the bump. A part of an external terminal (bump) of the logic die LD and a part of an external terminal (bump) of the processor PRC are connected to the package substrate via the silicon interposer SII. In the package substrate, the bump illustrated in the lower side of FIG. 3 is connected to, for example, a motherboard or the like of an information processing device or the like (server or the like) which is not illustrated.

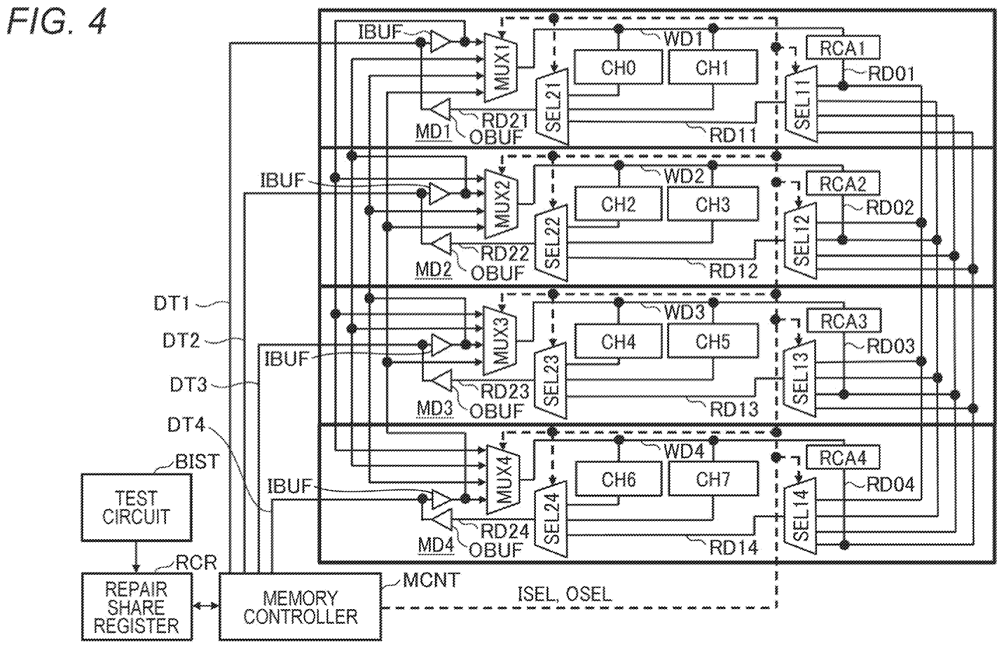

FIG. 4 illustrates an example of the memory die MD in FIG. 2. Each memory die MD includes a multiplexer MUX (MUX1, MUX2, MUX3, or MUX4) in addition to the two channels CH and the redundant cell region RCA illustrated in FIG. 2, Furthermore, each memory die MD includes selectors SEL1 (SEL11, SEL12, SEL13, or SEL14) and SEL2 (SEL21, SEL22, SEL23, or SEL24). The selector SEL1 is an example of a first output selection unit, and the selector SEL2 is an example of a second output selection unit.

Because the memory dies MD1 to MD4 have the same configuration, the memory die MD1 will be described below. The multiplexer MUX1 receives write data output by the memory controller MCNT in response to a writing command for the memory die MD1 via the data line DT1 and an input buffer IBUF. Furthermore, the multiplexer MUX1 receives write data output by the memory controller MCNT to the multiplexers MUX2 to MUX4 in response to writing commands for the other memory dies MD2 to MD4 via input buffers IBUF of the other memory dies MD2 to MD4.

Then, the multiplexer MUX1 selects any one piece of the received write data on the basis of the input selection signal ISEL generated by the memory controller MCNT and outputs the selected write data to the writing data line WD1. The writing data line WD1 is connected to data input terminals of the channels CH0 and CH1 and a data input terminal of the redundant cell region RCA.

The write data input to the multiplexer MUX of the local memory die MD (for example, MUX1 of MD1) via the input buffer IBUF is also input to the multiplexers MUX of other memory dies MD (for example, MUX2 to MUX4 of MD2 to MD4). In each memory die MD, the data input terminal that receives the data output from the input buffer IBUF of the other memory die MD and the data input terminal of the multiplexer MUX of the local memory die MD are connected via the TSV.

The selector SEL11 receives read data output from a data output terminal of the redundant cell region RCA1 of the local memory die MD1 via a reading data line RD01. Furthermore, the selector SEL11 receives read data output from data output terminals of the redundant cell regions RCA2 to RCA4 of the other memory dies MD2 to MD4 respectively via reading data lines RD02, RD03, and RD04. Then, the selector SEL11 selects any one piece of the received read data on the basis of the output selection signal OSEL generated by the memory controller MCNT and outputs the selected read data to a reading data line RD11.

A reading data line RD0 (for example, RD02 to RD04) connected to the data output terminal of the redundant cell region RCA of the other memory die MD and the data input terminal of the selector SEL1 (for example, SEL11) of the local memory die MD are connected to each other via the TSV.

The selector SEL21 receives the read data read from the local memory die MD1 or the redundant cell regions RCA2 to RCA4 of the other memory dies MD2 to MD4 via the reading data line RD11. Furthermore, the selector SEL21 receives the read data read from the channels CH0 and CH1. Then, the selector SEL21 selects any one piece of the received read data on the basis of the output selection signal OSEL generated by the memory controller MCNT and outputs the selected read data to a reading data line RD21. Note that the output selection signals OSEL received by the selectors SEL11 and SEL21 are different from each other.

The reading data line RD21 is connected to the data line DT1 via an output buffer OBUF. Then, the read data output from the output buffer OBUF is transferred to the memory controller MCNT as data stored in the memory die MD1.

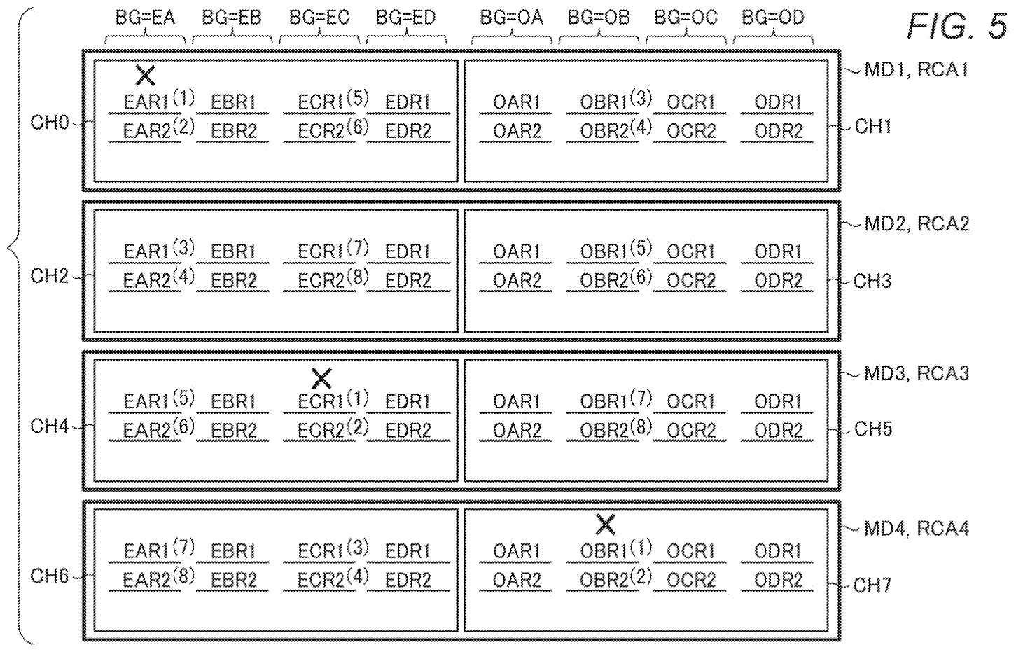

FIG. 5 illustrates an example in which a failure occurs in each of the channels CH0 to CH7 in FIG. 4 is relieved by the redundant cell region RCA. First, a configuration of each of the channels CH0 to CH7 will be described.

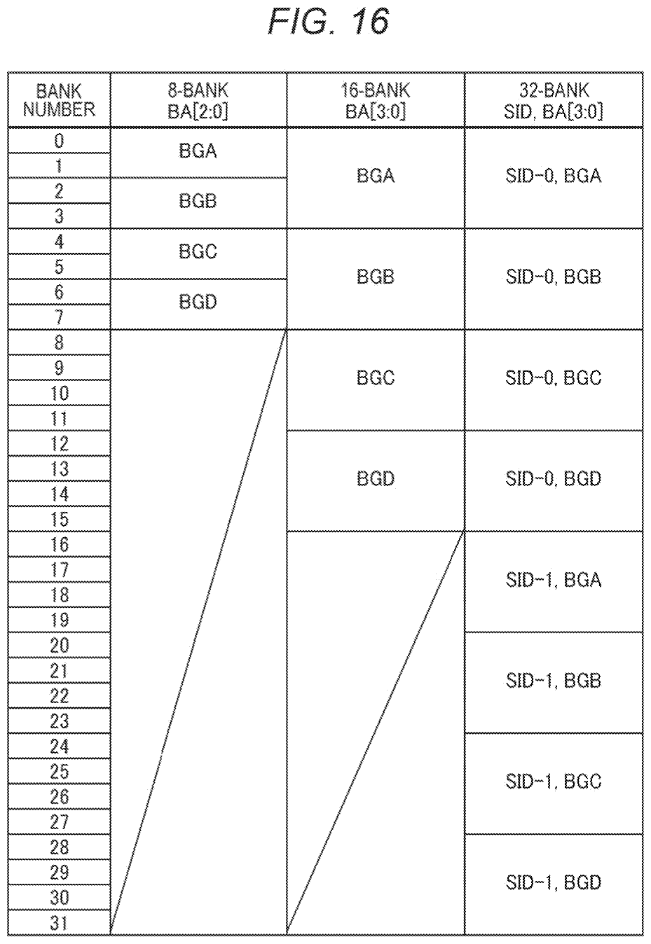

In the memory 102, even-numbered channels CH0, CH2, CH4, and CH6 arranged at positions opposed to each other include four bank groups BG (EA, EB, EC, and ED). Each bank group BG includes a plurality of banks. Furthermore, in the memory 102, odd-numbered channels CH1, CH3, CH5, and CH7 arranged at positions opposed to each other include four bank groups BG (OA, OB, OC, and OD). Each bank group BG includes a plurality of banks. An example of a configuration of the bank is illustrated in FIG. 16. The bank group BG is an example of a sub memory cell group that is a set of banks of which values of a predetermined number of bits of an allocated address are the same.

Each of the redundant cell regions RCA1 to RCA4 includes two redundant word lines for each bank group BG. For example, the redundant cell region RCA1 includes redundant word lines EAR1 and EAR2 corresponding to the bank group EA and redundant word lines EBR1 and EBR2 corresponding to the bank group EB. The redundant cell region RCA1 includes redundant word lines ECR1 and ECR2 corresponding to the bank group EC and redundant word lines EDR1 and EDR2 corresponding to the bank group ED.

Furthermore, the redundant cell region RCA1 includes redundant word lines OAR1 and OARZ corresponding to the bank group OA and redundant word lines OBR1 and OBR2 corresponding to the bank group OB. The redundant cell region RCA1 includes redundant word lines OCR1 and OCR2 corresponding to the bank group OC and redundant word lines ODR1 and ODR2 corresponding to the bank group OD.

Each of the other redundant cell regions RCA2 to RCA4 also includes redundant word lines E % R1 and E % R2 corresponding to a bank group E % (% is A, B, C, or D) and redundant word lines O % R1 and O % R2 corresponding to a bank group O % (% is A, B, C, or D).

Each bank group BG is an example of a sub memory cell region identified by a three-bit address of an address including four or more bits allocated to each channel. Furthermore, a region of each redundant cell region RCA where the two redundant word lines corresponding to each bank group BG are provided is an example of a sub redundant cell region.

In this embodiment, a failure is relieved by the redundant word line in bank group BG units. For example, in a case where a failure that can be relieved by the redundant word line is detected in the bank group EA of the channel CH0 (X mark in channel CH0), the test circuit BIST searches for an unused redundant word line from the redundant word line EAR1 of the local memory die MD1 in order. The search order is the order of (1) to (8) applied to the bank group EA and indicates priority order of the alternative of the failure.

Furthermore, in a case where a failure that can be relieved by the redundant word line is detected in the bank group EC of the channel CH4 (X mark in channel CH4), the test circuit BIST searches for an unused redundant word line from the redundant word line ECR1 of the local memory die MD3 in order. The search order is the order of (1) to (8) applied to the bank group EC and indicates priority order of the alternative of the failure.

Similarly, in a case where a failure that can be relieved by the redundant word line is detected in the bank group OB of the channel CH7 (X mark in channel CH7), the test circuit BIST searches for an unused redundant word line from the redundant word line OBR1 of the local memory die MD4 in order. The search order is the order of (1) to (8) applied to the bank group OB and indicates priority order of the alternative of the failure.

In this way, the redundant cell region RCA used to relieve the failure is selected between regions where the redundant word lines are provided in correspondence with the bank group BG (common address value) identified by a three-bit address. Accordingly, the selection processing can be simplified than a case where the test circuit BIST selects a redundant word line to be replaced from among all the redundant word lines, and it is possible to shorten a selection processing time. As a result, a power-on-sequence time of the processor PRC can be shortened, and an activation time of the processor PRC can be shortened.

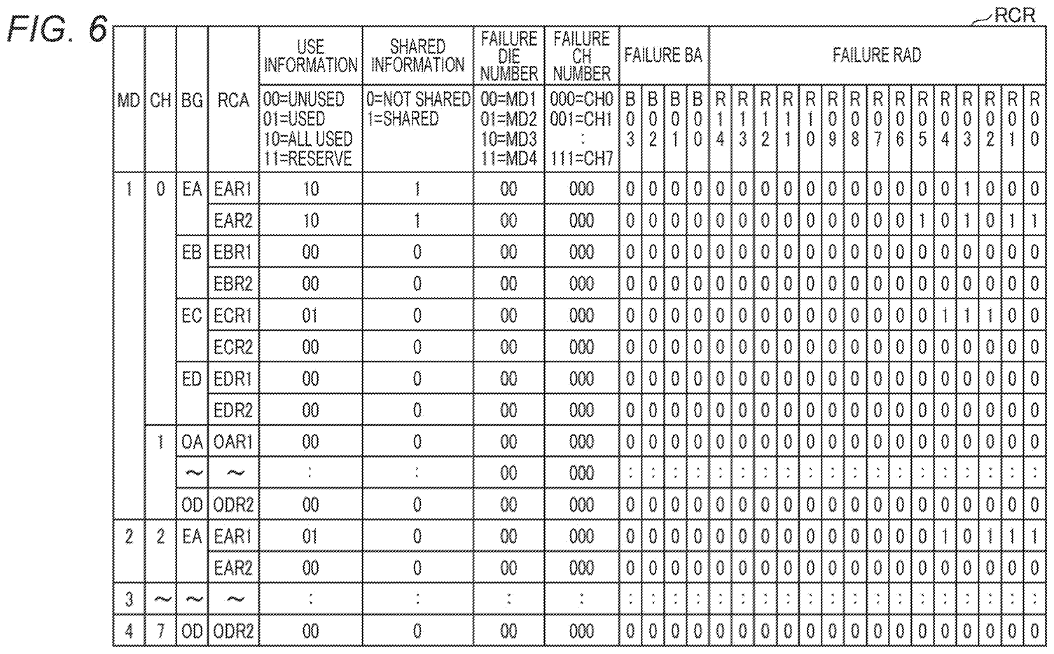

FIG. 6 illustrates an example of the repair share register RCR in FIG. 4. The repair share register RCR has an entry for each of the redundant word lines E % R1, E % R2, O % R1, and O % R2. Each entry includes regions where use information, shared information, a failure die number, a failure channel (CH) number, a failure bank address BA, and a failure row address RAD are stored. The use information is an example of the usage status of the redundant cell region RCA, and the shared information is an example of alternative information indicating an alternative using the redundant cell region RCA of the other memory die MD, The failure die number, the failure channel number, the failure bank address BA, and the failure row address RAD are examples of an address indicating a part of the channel CH having a failure.

The use information “00” indicates that a redundant word line corresponding to the bank group BG of each channel CH is not used, and the use information “01” indicates that the redundant word line corresponding to the bank group BG of each channel CH is in use. The use information “10” indicates that all the two redundant word lines in the bank group BG of each channel CH are in use. The use information “11” is reserved and is not used.

For example, in a case where a failure is relieved by using a first redundant word line in the bank group BG of the local memory die MD, the test circuit BIST sets use information of an entry corresponding to the first redundant word line to be used to “01”. In a case where a failure is relieved using a second redundant word line, the test circuit BIST sets use information of an entry corresponding to a pair of redundant word lines including the redundant word line to be used to “10”.

The shared information is valid in a case where the use information is “10”. The shared information “0” indicates that failure relief using a redundant word line of the other memory die MD is not performed (not shared). The shared information “1” indicates that the failure relief using the redundant word line of the other memory die MD is performed (shared).

In other words, for example, in a case where the two redundant word lines are used in the bank group BG of the local memory die MD and failure relief using the other memory die MD is performed, the test circuit BIST sets shared information of an entry corresponding to the two redundant word lines in use to “1”. The example illustrates in FIG. 6 indicates that all the two redundant word lines for relief of the bank group EA of the channel CH0 of the memory die MD1 are in use, and a third failure is relieved using the redundant word line EAR1 of the bank group EA of the channel CH2 of the other memory die MD2.

The failure die number is valid in a case where the use information is “01” or “10”. The failure die number indicates a number of the memory die MD of which a failure is relieved using a redundant word line. In a case where a failure of the memory die MD1 is relieved, the test circuit BIST sets the failure die number to “00”, and in a case where a failure of the memory die MD2 is relieved, the test circuit BIST sets the failure die number to “01”. In a case where a failure of the memory die MD3 is relieved, the test circuit BIST sets the failure die number to “10”, and in a case where a failure of the memory die MD4 is relieved, the test circuit BEST sets the failure die number to “11”.

The failure bank address BA is a bank address BA indicating a bank in which a failure (malfunction) is detected, and the failure row address RAD is a row address RAD indicating a word line in which a failure (malfunction) is detected.

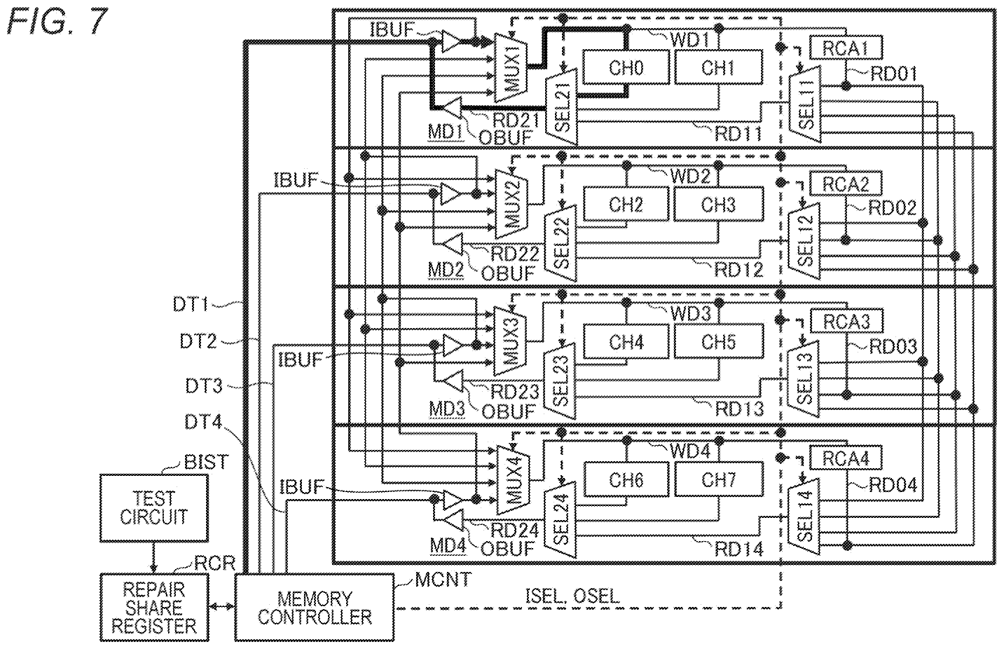

FIG. 7 illustrates an example of a normal operation that does not use the redundant cell region RCA in the memory 102 in FIG. 2. At the time of the operation in FIG. 7, it is assumed that the state of the repair share register RCR be a state illustrated in FIG. 6. A thick signal line in FIG. 7 indicates a path through which data is transferred. In the example illustrated in FIG. 7, the memory controller MCNT sequentially receives reading requests and writing requests from the processor PRC (FIG. 2) to the bank group EA of the channel CH0.

The memory controller MCNT refers to the bank group B of the channel CH0 of the repair share register RCR on the basis of the writing request and determines that no entry stores an address included in the writing request (replacement is not performed). Here, in a case where use information in both of the two entries of the bank group EB of the channel CH0 of the repair share register RCR is “00”, it is determined that the replacement is not performed.

Note that, in a case where an address to be accessed is not stored in an entry having use information “01” of two entries of an arbitrary bank group BG of an arbitrary channel CH of the repair share register RCR, it is determined that the replacement is not performed. Furthermore, in a case where an address to be accessed is not stored in an entry having use information “10” of two entries of an arbitrary bank group BG of an arbitrary channel CH of the repair share register RCR and the shared information is “0”, it is determined that the replacement is not performed. Alternatively, in a case where shared information of a predetermined bank group BG of an arbitrary channel CH of the repair share register RCR is “1” and an address to be accessed is not stored in an entry of a predetermined bank group BG of other channel CH, it is determined that the replacement is not performed.

The memory controller MCNT outputs the input selection signal ISEL that selects a data line DT1 corresponding to the channel CH0 to be accessed to the multiplexer MUX1. Furthermore, the memory controller MCNT outputs a writing command corresponding to the writing request to the channel CH0 and outputs write data to the data line DT1.

In response to the writing command, the input buffer IBUF connected to an input of the multiplexer MUX1 is turned on. As a result, the write data supplied to the data line DT1 is transferred to the writing data line WD1 via the input buffer IBUF and the multiplexer MUX1 and is written to the channel CH0.

Next, the memory controller MCNT refers to the repair share register RCR on the basis of the reading request and determines that no entry stores an address included in the reading request. The memory controller MCNT outputs the output selection signal OSEL that selects an output of the channel. CH0 to the selector SEL21. Furthermore, the memory controller MCNT outputs a reading command corresponding to the reading request to the channel CH0.

In response to the reading command, the output buffer OBUF connected to an output of the selector SEL21 is turned on. With this state, the read data read from the channel CH0 is output to the data line DT1 via the selector SEL21, the reading data line RD21, and the output buffer OBUF and is transferred to the memory controller MCNT.

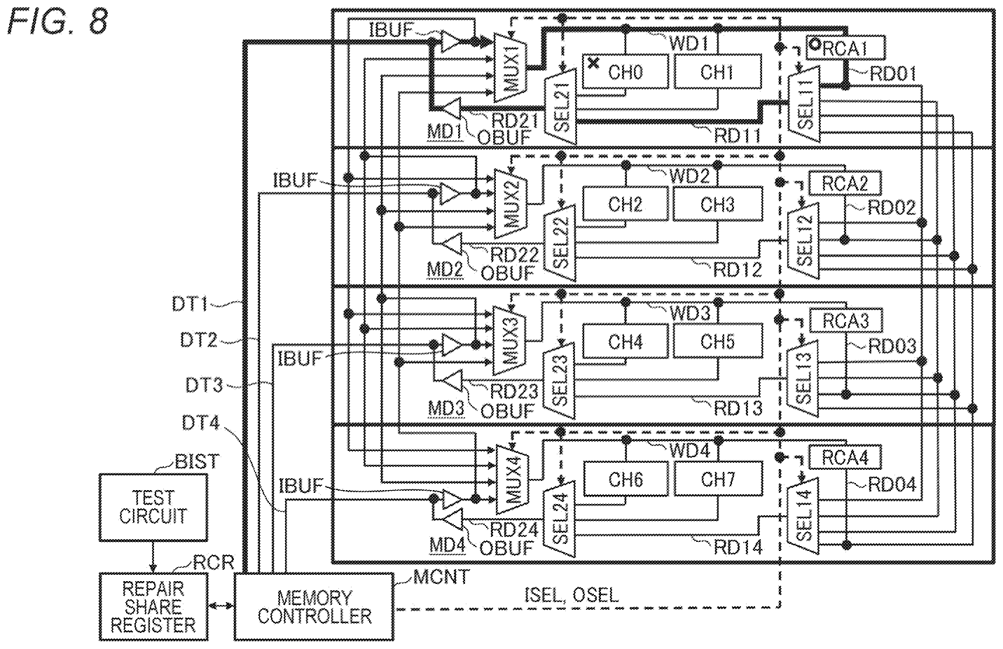

FIG. 8 illustrates an example of an alternative operation using the redundant cell region RCA in the memory 102 in FIG. 2. Detailed description of operations similar to those in FIG. 7 will be omitted. At the time of the operation in FIG. 8, it is assumed that the state of the repair share register RCR be a state illustrated in FIG. 6, In the example illustrated in FIG. 8, the memory controller MCNT sequentially receives reading requests and writing requests from the processor PRC to the bank group EA of the channel CH0. A memory cell of the channel CH0 to be accessed is replaced with the redundant cell region RCA1 due to a failure of the memory cell itself, the word line, or the like. The X mark in the channel CH0 indicates a failure, and a circle in the redundant cell region RCA1 indicates relief of the failure.

The memory controller MCNT refers to the repair share register RCR in response to the writing request and determines that use information of an entry corresponding to the bank group EA and the channel CH0 is “01”. Then, the memory controller MCNT determines that an address included in the writing request is stored in an entry corresponding to the channel CH0, the bank group EA, and the redundant word line EARL

The memory controller MCNT outputs a writing command to the redundant cell region RCA1 in response to the writing request and outputs write data to the data line DT1. The operation before the write data is transferred to the writing data line WD1 is similar to that in FIG. 7. Then, the write data transferred to the writing data line WD1 is written to the redundant cell region RCA1.

Next, the memory controller MCNT refers to the repair share register RCR in response to the reading request and determines that an address included in the reading request is stored in the entry corresponding to the channel CH0, the bank group EA, and the redundant word line EAR1. The memory controller MCNT outputs an output selection signal OSEL that selects an output of the redundant cell region RCA1 (reading data line RD01) to the selector SEL11.

Furthermore, the memory controller MCNT outputs an output selection signal OSEL that selects an output of the selector SEL11 (reading data line RD11) to the selector SEL21. The memory controller MCNT outputs the reading command corresponding to the reading request to the redundant cell region RCM. Then, the read data read from the redundant cell region RCA1 is output to the data line DT1 via the reading data lines RD01, RD11, and RD21 and the output buffer OBUF and is transferred to the memory controller MCNT.

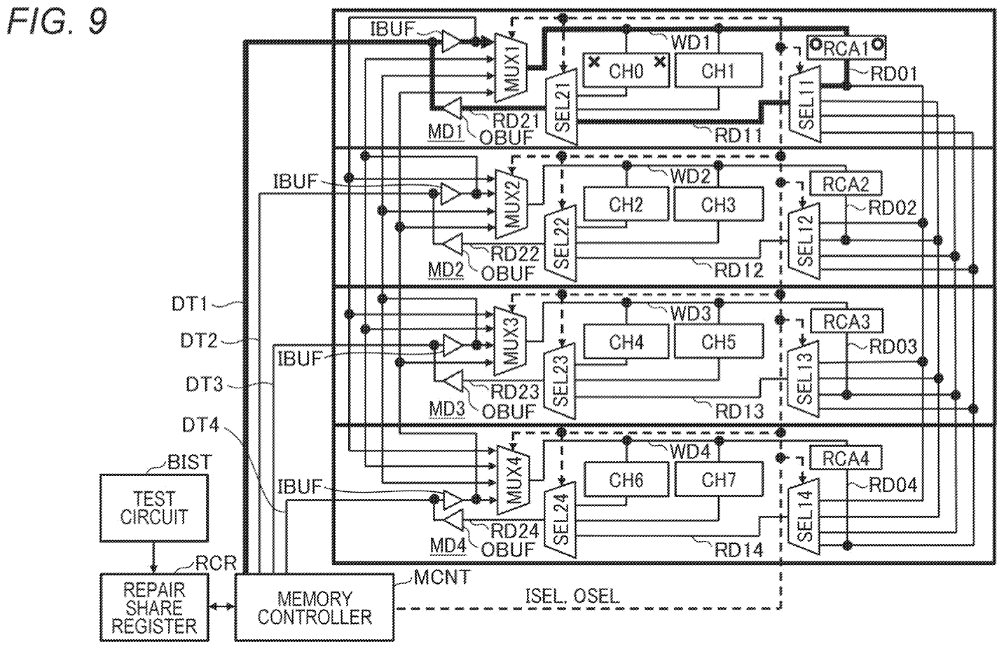

FIG. 9 illustrates another example of the alternative operation using the redundant cell region RCA in the memory 102 in FIG. 2. Detailed description of operations similar to those in FIGS. 7 and 8 will be omitted. At the time of the operation in FIG. 9, it is assumed that the state of the repair share register RCR be a state illustrated in FIG. 6. In the example illustrated in FIG. 9, the memory controller MCNT sequentially receives writing requests and reading requests from the processor PRC to the channel CH0 of the memory die MD1. However, as in FIG. 8, the memory cell of the channel CH0 to be accessed is replaced by using the redundant cell region RCA1.

The memory controller MCNT refers to the repair share register RCR in response to the writing request and determines that an address included in the writing request is stored in the entry corresponding to the channel CH0, the bank group EA, and the redundant word line EAR2. Therefore, as in FIG. 8, the memory controller MCNT controls the multiplexer MUX1, outputs the writing command to the redundant cell region RCA1, and writes the write data to the redundant cell region RCA1.

Next, the memory controller MCNT refers to the repair share register RCR in response to the reading request and determines that an address included in the reading request is stored in the entry corresponding to the channel CH0, the bank group EA, and the redundant word line EAR2. Therefore, as in FIG. 8, the memory controller MCNT controls the selectors SEL11 and SEL21, outputs the reading command to the redundant cell region RCA1, and receives the read data read from the redundant cell region RCA1 via the data line DT1.

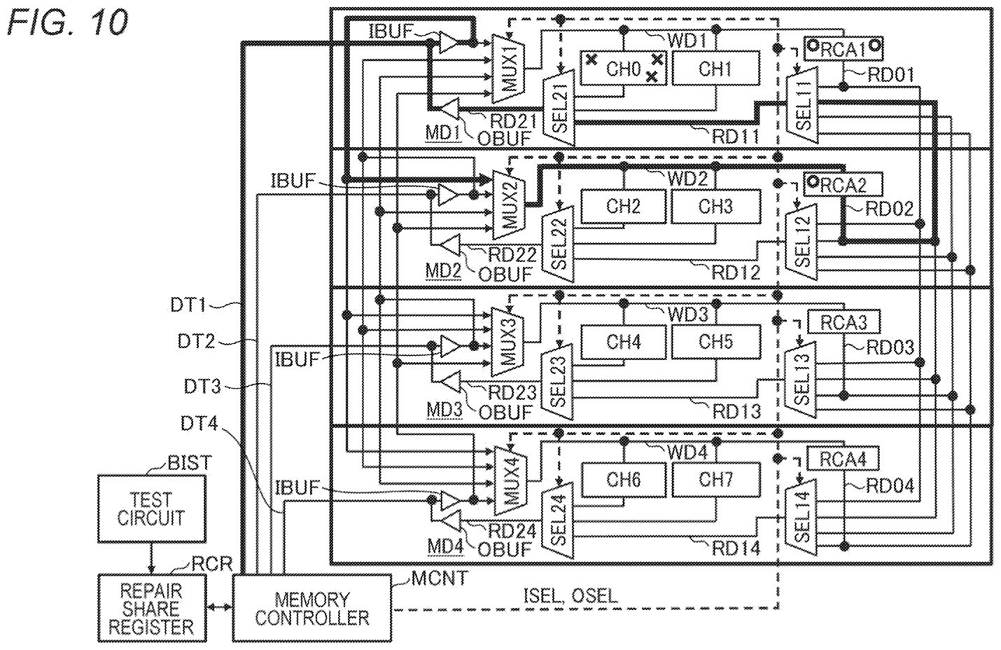

FIG. 10 illustrates still another example of the alternative operation using the redundant cell region RCA in the memory 102 in FIG. 2. Detailed description of operations similar to those in FIGS. 7 to 9 will be omitted. At the time of the operation in FIG. 10, it is assumed that the state of the repair share register RCR be a state illustrated in FIG. 6. In the example illustrated in FIG. 10, the memory controller MCNT sequentially receives writing requests and reading requests from the processor PRC to the channel CH0 of the memory die MD1. However, the memory cell of the channel CH0 to be accessed is replaced with the redundant cell region RCA2 due to a failure of the memory cell itself, the word line, or the like. In other words, for example, all the redundant word lines EAR1 and EAR2 of the redundant cell region RCA1 are used as an alternative of a failure.

The memory controller MCNT refers to the repair share register RCR in response to the writing request and determines that the use information of the entry corresponding to the channel CH0 and the bank group EA is “10” and both pieces of the shared information are “1”. Furthermore, the memory controller MCNT determines that the address included in the writing request is not stored in the entry corresponding to the channel CH0 and the bank group EA. In this case, the memory controller MCNT determines whether or not an address to be accessed is stored in the entries of the bank groups EA of the other channels CH2, CH4, and CH6.

In the example illustrated in FIG. 10, the address to be accessed is stored in the entry corresponding to the redundant word line EAR1 of the bank group EA of the channel CH2. Therefore, the memory controller MCNT outputs the writing command to the redundant cell region RCA2 of the memory die MD2 in response to the writing request.

The memory controller MCNT outputs an input selection signal ISEL that selects a data line connected to an input of the multiplexer MUX2 of the memory die MD2 to the multiplexer MUX2. Furthermore, the memory controller MCNT outputs the writing command corresponding to the writing request to the redundant cell region RCA2 of the memory die MD2 and outputs the write data to the data line DT1.

In response to the writing command, the input buffer IBUF connected to an input of the multiplexer MUX1 is turned on. As a result, the write data supplied to the data line DT1 is transferred to the input of the multiplexer MUX2. Then, the write data is transferred to the writing data line WD2 via the multiplexer MUX2 and is written to the redundant cell region RCA2.

Next, the memory controller MCNT refers to the repair share register RCR in response to the reading request and determines that a word line connected to a memory cell to be read is replaced with the redundant word line EAR1 of the redundant cell region RCA2 of the memory die MD2. Therefore, the memory controller MCNT outputs an output selection signal OSEL used to select an output of the redundant cell region RCA2 (reading data line RD02) to the selector SEL11 of the memory die MD1.

Furthermore, as in FIG. 8, the memory controller MCNT outputs the output selection signal OSEL used to control the selector SEL21 and outputs the reading command corresponding to the reading request to the redundant cell region RCA2 of the memory die MD2. Then, the read data read from the redundant cell region RCA2 is output to the data line DT1 via the reading data lines RD02, RD11, and RD21 and the output buffer OBUF and is transferred to the memory controller MCNT.

In this way, by controlling the multiplexer MUX on the basis of the information held in the repair share register RCR, data can be written to the redundant cell region RCA of the other memory die MD instead of writing data to a channel CH which is partially failed. Furthermore, by controlling the selectors SEL1 and SEL2 on the basis of the information held in the repair share register RCR, data can be read from the redundant cell region RCA of the other memory die MD instead of reading data from a channel CH which is partially failed. At this time, the write data and the read data can be transferred to the data line DT corresponding to the channel CH to be accessed. Therefore, the memory controller MCNT can control the writing operation and the reading operation of the memory 102 without, for example, switching the path of the data lines, through which data is transferred, in the memory controller MCNT.

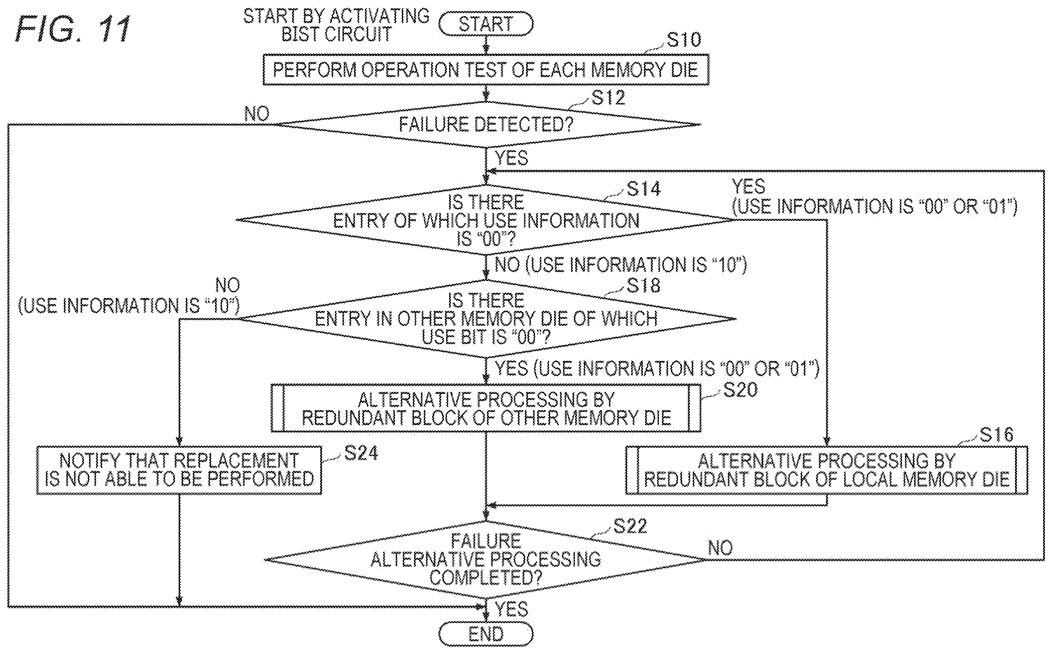

FIG. 11 illustrates an example of an operation of the test circuit BIST in FIG. 2. The operation illustrated in FIG. 11 is started by activating the test circuit BIST. The test circuit BIST is activated when the memory 102 is turned on or in response to an activation request from outside.

First, in step S10, the test circuit BIST performs an operation test of each memory die MD. Next, in step S12, in a case of detecting a failure, the test circuit BIST executes step S14, and in a case of detecting no failure, the test circuit BIST terminates the operation illustrated in FIG. 11. Note that it is assumed that the failure detected in step S12 be a failure that can be relieved by the redundant cell region RCA. Furthermore, the operations in and subsequent to step S12 are executed for each of the bank groups BG of the respective even-numbered channels CH0, CH2, CH4, and CH6 and for each of the bank groups BG of the respective odd-numbered channels CH1, CH3, CH5, and CH7.

In step S14, the test circuit BIST refers to the repair share register RCR and, in a case where use information of one of two entries of the bank group BG of the memory die MD in which the failure is detected is “00”, the test circuit BIST executes step S16. In a case where both pieces of the use information of the two entries of the bank group BG of the memory die MD in which the failure is detected are “10”, the test circuit BIST executes step S18.

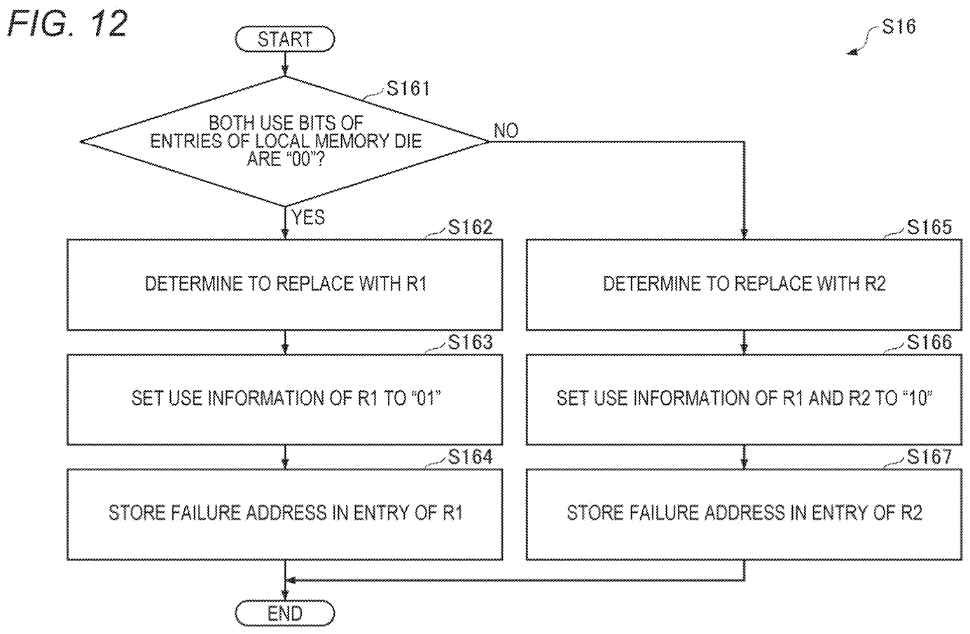

In step S16, the test circuit BIST executes failure alternative processing using the redundant cell region RCA of the memory die MD in which the failure is detected. An example of step S16 is illustrated in FIG. 12. In step S18, the test circuit BIST refers to the repair share register RCR and, in a case where use information of one of two entries of each bank group BG other than the memory die MD in which the failure is detected is “00”, the test circuit BIST executes step S20. In a case where both pieces of the use information of the two entries of each bank group BG other than the memory die MD in which the failure is detected are “10”, the test circuit BIST executes step S24.

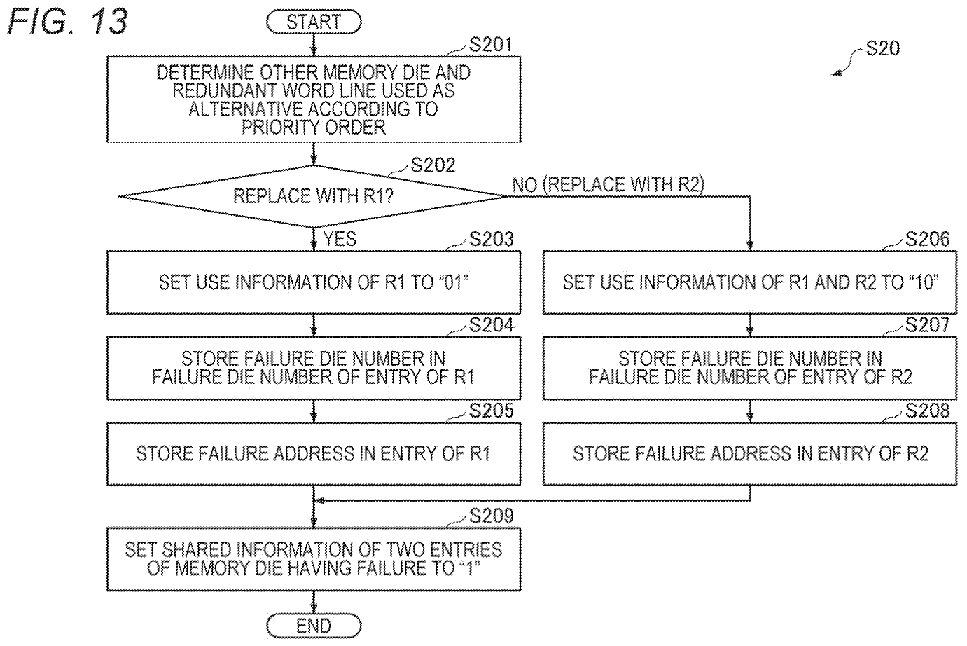

In step S20, the test circuit BIST executes the failure alternative processing using the redundant cell region RCA of the other memory die MD different from the memory die MD in which the failure is detected. An example of step S20 is illustrated in FIG. 13. After steps S16 and S20, step S22 is executed.

In step S22, in a case where all the failure alternative processing based on the result of the operation test has been completed, the test circuit BIST completes the operation illustrated in FIG. 11. In a case where the failure alternative processing is not completed, the test circuit BIST returns the processing to step S14. In step S24, because no redundant word line that can be replaced with the failure remains, the test circuit BIST notifies a host device such as the processor PRC of that it is not possible to perform replacement (in other words for example, failure of memory 102), and terminates the operation in FIG. 11.

Note that the operation illustrated in FIG. 11 may be executed by an alternative determination circuit other than the test circuit provided in the logic die LD or may be executed by the memory controller MCNT. In a case where the operation illustrated in FIG. 11 is executed by the alternative determination circuit or the memory controller MCNT, step S10 is executed by the test circuit BIST. The alternative determination circuit or the memory controller MCNT receives a test execution result from the test circuit BIST and executes the operations in and subsequent to step S12.

FIG. 12 illustrates an example of the operation in step S16 in FIG. 11. First, in step S161, the test circuit BIST refers to the repair share register RCR, and in a case where the use Information of the two entries of the bank group BG of the memory die MD in which the failure is detected is “00”, the failure is not replaced. Therefore, the test circuit BIST executes step S162. In a case where one of the pieces of the use information of the two entries of the bank group BG of the memory die MD in which the failure is detected is “01”, one failure has been replaced. Therefore, the test circuit BIST executes step S165.

In step S162, the test circuit BIST determines to replace the failure with a redundant word line having R1 at the end. Next, in step S163, the test circuit BIST sets use information of an entry corresponding to the redundant word line having R1 at the end to “01”. Next, in step S164, the test circuit BIST stores a failure address in regions of a failure die number, a failure channel number, a failure bank address BA, and a failure row address RAD of the entry corresponding to the redundant word line having R1 at the end and completes the operation illustrated in FIG. 12.

In step S165, the test circuit BIST determines to replace the failure with a redundant word line having R2 at the end. Next, in step S166, the test circuit MST sets use information of the entries corresponding to the redundant word lines having R1 and R2 at the ends to “10. Next, in step S167, the test circuit BIST stores a failure address in regions of a failure die number, a failure channel number, a failure bank address BA, and a failure row address RAD of the entry corresponding to the redundant word line having R2 at the end and completes the operation illustrated in FIG. 12.

FIG. 13 illustrates an example of the operation in step S20 in FIG. 11. First, in step S201, the test circuit BIST searches the repair share register RCR and determines the other memory die MD and a redundant word line to be used as an alternative according to the priority order described with reference to FIG. 5. Next, in step S202, in a case where the failure is replaced with the redundant word line having R1 at the end, the test circuit BIST executes step S203, and in a case where the failure is replaced with the redundant word line having R2 at the end, the test circuit BIST executes step S206.

In step S203, the test circuit BET sets use information of an entry corresponding to the redundant word line having R1 at the end to “01”. Next, in step S204, the test circuit BIST stores a die number of a memory die MD in which the failure is detected in the failure die number of the entry corresponding to the redundant word line having R1 at the end. Next, in step S205, the test circuit BIST stores a failure address in the regions of the failure channel number CH, the failure bank address BA, and the failure row address RAD of the entry corresponding to the redundant word line having R1 at the end and executes step S209.

On the other hand, in step S206, the test circuit MST sets use information of the entries corresponding to the redundant word lines having R1 and R2 at the ends to “10. Next, in step S207, the test circuit BIST stores the die number of the memory die MD in which the failure is detected in the failure die number of the entry corresponding to the redundant word line having R2 at the end, Next, in step S208, the test circuit BIST stores a failure address in the regions of the failure channel number CH, the failure bank address BA, and the failure row address RAD of the entry corresponding to the redundant word line having R2 at the end and executes step S209.

In step S209, the test circuit BIST sets the shared information of the two entries of the bank group BG of the memory die MD in which the failure is detected to “1” and terminates the operation illustrated in FIG. 13.

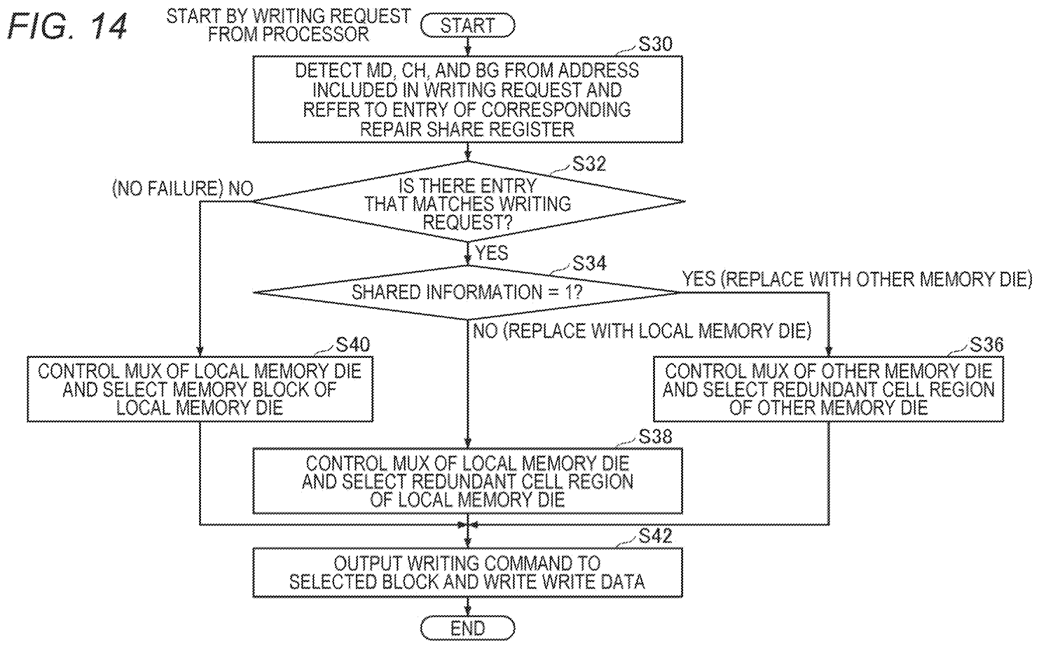

FIG. 14 illustrates an example of an operation of the memory controller MCNT that controls the writing operation of the memory 102 in FIG. 2. The operation illustrated in FIG. 14 is started on the basis of receipt of a writing request from the processor PRC.

First, in step S30, the memory controller MCNT detects a memory die MD to which data is written, a channel CH, and a bank group BG from an access address included in the writing request. Then, the memory controller MCNT refers to an entry corresponding to the detected memory die MD, channel CH, and bank group BG in the repair share register RCR. Here, the entry to be referred includes an entry corresponding to the channel CH and the bank group BG detected from the address included in the writing request not only in the memory die MD to be accessed but also in the other memory die MD.

Next, in step S32, in a case where there is an entry that matches the writing request, the failure is replaced. Therefore, the memory controller MCNT executes step S34. In a case where there is no entry that matches the writing request, no failure occurs. Therefore, the memory controller MCNT executes step S40. Here, the entry that matches the writing request is an entry corresponding to the bank group BG in which the failure is detected and is an entry of which use information is “01” or “10” and of which the address matches that of the writing request. Furthermore, the match of the address is determined based on the failure die number, the failure channel number CH, the failure bank address BA, and the failure row address RAD. Note that detection of the entry that matches the writing request in the other memory die MD is valid in a case where the shared information of the entry of the bank group BG of the memory die MD in which the failure is detected is “1”.

In step S34, in a case where the shared information of the entry of the bank group BG of the memory die MD in which the failure is detected is “1”, the memory controller MCNT executes step S36, and in a case where the shared information is “0”, the memory controller MCNT executes step S38. In step S36, in order to perform replacement with the redundant cell region RCA of the other memory die MD, the memory controller MCNT controls the multiplexer MUX of the other memory die MD and selects the redundant cell region RCA of the other memory die MD, and thereafter, the memory controller MCNT executes step S42.

In step S38, in order to perform replacement with the redundant cell region RCA of the local memory die MD, the memory controller MCNT controls the multiplexer MUX of the local memory die MD and selects the redundant cell region RCA of the local memory die MD, and thereafter, the memory controller MCNT executes step S42.

In step S40, in order to write data to the channel CH of the local memory die MD, the memory controller MCNT controls the multiplexer MUX of the local memory die MD and selects the channel. CH of the local memory die MD, and thereafter, the memory controller MCNT executes step S42.

In step S42, the memory controller MCNT outputs the writing command to the selected block (redundant cell region RCA or channel CH), writes the write data, and terminates the writing operation in response to the writing access request illustrated in FIG. 14.

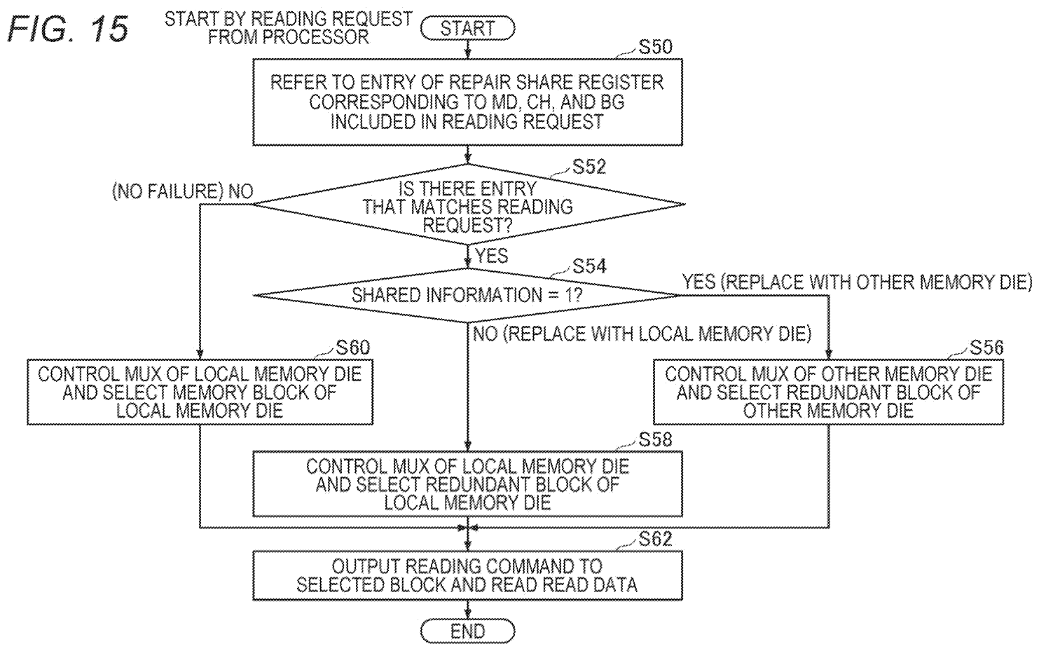

FIG. 15 illustrates an example of an operation of the memory controller MCNT that controls the reading operation of the memory 102 in FIG. 2. Detailed description of operations similar to those in FIG. 14 will be omitted. The operation illustrated in FIG. 15 is started on the basis of receipt of a reading request from the processor PRC.

First, in step S50, the memory controller MCNT detects a memory die MD from which data is read, a channel CH, and a bank group BG from an access address included in the reading request. Then, the memory controller MCNT refers to an entry corresponding to the detected memory die MD, channel CH, and bank group BG in the repair share register RCR. As in FIG. 14, the entry to be referred includes an entry corresponding to the channel CH and the bank group BG detected from the address included in the reading request not only in the memory die MD to be accessed but also in the other memory die MD.

Next, in step S52, in a case where there is an entry that matches the reading request, the failure is replaced. Therefore, the memory controller MCNT executes step S54. In a case where there is no entry that matches the reading request, no failure occurs. Therefore, the memory controller MCNT executes step S60. Here, the entry that matches the reading request is an entry corresponding to the bank group BG in which the failure is detected and is an entry of which use information is “01” or “10” and of which the address matches that of the writing request. Furthermore, the match of the address is determined based on the failure die number, the failure channel number CH, the failure bank address BA, and the failure row address RAD. Note that detection of the entry that matches the reading request in the other memory die MD is valid in a case where the shared information of the entry of the bank group BG of the memory die MD in which the failure is detected is “1”.

Steps S54, S56, S58, and S60 are respectively similar to steps S34, S36, S38, and S40 illustrated in FIG. 14. After steps S56, S58, and S60, in step S62, the memory controller MCNT outputs a reading command to the selected block (redundant cell region RCA or channel CH). Then, the memory controller MCNT reads the read data and terminates the reading operation in response to a reading access request illustrated in FIG. 15.

FIG. 16 illustrates an example of a bank configuration of the memory 102 in FIG. 2. The memory 102 is designed by using an 8-bank configuration, a 16-bank configuration, or a 32-bank configuration. The bank groups BG illustrated in FIG. 16 are indicated without distinguishing odd-numbered channels CH and even-numbered channels CH from each other. In a case of the 8-bank configuration, a three-bit bank address BA [2:0] is used, and two banks are allocated to each bank group BG (BGA, BGB, BGC, and BGD). In a case of the 16-bank configuration, a four-bit bank address BA [3:0] is used, and four banks are allocated to each bank group BG. In a case of the 32-bank configuration, the four-bit bank address BA [3:0] and a stack ID (SID) are used, and four banks are allocated to each bank group BG for each stack ID.

As described above, in the embodiment illustrated in FIGS. 2 to 16, similar effects to those in the embodiment illustrated in FIG. 1 can be obtained. For example, by controlling the operations of the multiplexer MUX and the selector SEL on the basis of an external signal without mounting the fuse circuit that stores the failure address and the comparison circuit of the failure address, the redundant cell region RCA that relieves the failure can be selected. As a result, an increase in the access latency can be suppressed as compared with a case where whether or not to replace the failure in a part of the channel CH with the local memory die MD or the redundant cell region RCA of the other memory die MD is determined in the memory die MD.

The memory controller MCNT can perform the redundant determination for determining whether or not to perform replacement by using the repair share register RCR provided in the memory controller MCNT. With this operation, the memory controller MCNT can perform the redundant determination while holding the access request received from outside (before issuing access command to memory die MD), and can make the time needed for the redundant determination be invisible.

Moreover, in the embodiment illustrated in FIGS. 2 to 16, the redundant cell region RCA used to relieve the failure is selected between regions where the redundant word lines are provided in correspondence with the bank group BG (common address value) identified by a three-bit address. Accordingly, the selection processing can be simplified than a case where a redundant word line to be used by the test circuit BIST is selected from among all the redundant word lines, and it is possible to shorten a selection processing time. As a result, a power-on-sequence time of the processor PRC can be shortened, and an activation time of the processor PRC can be shortened.

From the above detailed description, characteristics and advantages of the embodiments will become apparent. This is intended to cover the features and advantages of the embodiments described above without departing from the spirit and the scope of the claims. Furthermore, any person having ordinary knowledge in the technical field can be easily come up with various improvements and modifications, Therefore, there is no intention to limit the scope of the inventive embodiments to those described above, and the scope of the inventive embodiments can rely on appropriate improvements and equivalents included in the scope disclosed in the embodiments.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention, Although one or more embodiments of the present invention have been described in detail, it should be understood that the various changes, substitutions, and alterations could be made hereto without departing from the spirit and scope of the invention.

What is claimed is:

1. A memory comprising:
a plurality of memory dies that includes a plurality of memory regions stacked on each other, the plurality of memory regions including a memory cell region that stores data and a redundant cell region that stores data as an alternative when a part of the memory cell region fails;
a multiplexer that outputs data supplied to a local memory region or data supplied to another memory region to the redundant cell region of the local memory region on a basis of an input selection signal from outside; and
a selector that outputs data output from the redundant cell region of the local memory region or data output from the redundant cell region of the other memory region to a data terminal of the local memory region on a basis of an output selection signal from outside.

2. The memory according to claim 1, further comprising:
a repair share register configured to hold a usage status of the redundant cell region, an address that indicates a part of the failed memory cell region, and alternative information that indicates an alternative by the redundant cell region of the other memory region; and
a memory controller configured to control an access of the memory region and generate the input selection signal and the output selection signal on a basis of information held by the repair share register.

3. The memory according to claim 2, further comprising
a test circuit configured to test an operation of the plurality of memory regions and store information in the repair share register on a basis of a test result.

4. The memory according to claim 2, further comprising
a plurality of data lines respectively connected between the memory controller and the plurality of memory regions.

5. The memory according to claim 1, wherein
each of the memory cell regions of the plurality of memory regions includes a plurality of sub memory cell regions identified by a predetermined number of bits in an address of a plurality of bits used to identify the memory cell region,
the redundant cell region includes a plurality of sub redundant cell regions that respectively corresponds to the plurality of sub memory cell regions, and
in the memory cell region of the plurality of memory regions, a failure in a sub memory cell group that is a set of sub memory cell regions of which values of the predetermined number of bits are the same is able to be replaced with any one of the sub redundant cell regions that correspond to the sub memory cell group.

6. The memory according to claim 1, wherein
the plurality of memory regions is respectively included in a plurality of memory dies,
a data input terminal that receives data that is supplied to another memory region and is transferred from the other memory region is connected to a data input terminal of the multiplexer via a through electrode, and
a data output terminal of the redundant cell region of the local memory region is connected to a data input terminal of the selector of the other memory region via a through electrode.
